(19) United States
(12) Patent Application Publication
(10) Pub. No.: US 2026/0025955 A1
(43) Pub. Date: Jan. 22, 2026

(54) HEAT DISSIPATING STRUCTURE HAVING HIGH THERMAL CONDUCTIVITY

(71) Applicant: CMTEK Co., Ltd., Hsinchu City (TW)

(72) Inventors: CHIN-JUI LIANG, Hsinchu City (TW); CHIN-PING LIN, Hsinchu City (TW)

(21) Appl. No.: 19/015,983

(22) Filed: Jan. 10, 2025

(30) Foreign Application Priority Data
Jul. 17, 2024 (TW) 113207646

(51) Int. Cl. H05K 7/20

(52) U.S. Cl. CPC H05K 7/2039

(57) ABSTRACT

A heat dissipating structure having high thermal conductivity includes a non-sintered ceramic-based carrier layer and a metal surface layer. The non-sintered ceramic-based carrier layer is incorporated therein with at least one high thermal conductivity material. The metal surface layer is coated on an outside of the non-sintered ceramic-based carrier layer.

### CROSS-REFERENCE TO RELATED PATENT APPLICATION

This application claims the benefit of priority to Taiwan Patent Application No. 113207646, filed on Jul. 17, 2024. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a heat dissipating structure, and more particularly to a heat dissipating structure having high thermal conductivity.

### BACKGROUND OF THE DISCLOSURE

Composite material-based heat dissipating structures have been widely used in the field of electronics for dissipation of heat generated by electronic products during operation, thereby ensuring that the electronic products can operate under normal temperatures.

Ceramic and metal materials are commonly used for heat dissipating structures due to their good thermal conductivity and mechanical properties. In order to reduce the usage of more expensive materials and allow heat dissipating components (such as heat dissipating substrates) to benefit from the properties of multiple materials, different heat dissipating materials are used in combination in the heat dissipating components. Therefore, the purposes of reducing manufacturing costs and improving performance of the heat dissipating components can be achieved.

Composite material-based heat dissipating components require a special process to form the combination of multiple materials into a desired form or shape, so as to have properties suitable for practical applications. Such a process needs to take into account factors such as the physical and chemical properties of various heat dissipating materials and base materials, as well as structural properties required for the heat dissipating components, so that the heat dissipating components can have both good heat dissipation performance and suitable mechanical properties. However, most of the conventional heat dissipating components cannot achieve such good properties and tend to involve a complex manufacturing process. Therefore, there is still much room for improvement and many limitations in the practical application of heat dissipating components.

### SUMMARY OF THE DISCLOSURE

In response to the above-referenced technical inadequacies, the present disclosure provides a heat dissipating structure having high thermal conductivity. The heat dissipating structure has the advantages of good heat dissipation and a simple manufacturing process, producing a product that has a good heat dissipation effect and that is advantageous for increasing heat dissipation performance of a heat spreader.

In order to solve the above-mentioned problems, one of the technical aspects adopted by the present disclosure is to provide a heat dissipating structure having high thermal conductivity, which includes a non-sintered ceramic-based carrier layer and a metal surface layer. The non-sintered ceramic-based carrier layer is incorporated therein with at least one high thermal conductivity material. The metal surface layer is coated on an outside of the non-sintered ceramic-based carrier layer.

In one of the possible or preferred embodiments, the non-sintered ceramic-based carrier layer includes a ceramic layer and a metal-ceramic composite layer stacked on the ceramic layer, and the at least one high thermal conductivity material is incorporated into the metal-ceramic composite layer.

In one of the possible or preferred embodiments, the non-sintered ceramic-based carrier layer has a porosity of less than 65%.

In one of the possible or preferred embodiments, a thickness of the non-sintered ceramic-based carrier layer ranges from 0.1 mm to 6 mm, and a thickness of the metal surface layer ranges from 0.1 mm to 9 mm.

In one of the possible or preferred embodiments, the at least one high thermal conductivity material is selected from the group consisting of monocrystalline silicon, diamond, diamond-like carbon, boron nitride, and graphene.

In one of the possible or preferred embodiments, the at least one high thermal conductivity material is present in the form of particles having a particle size of less than 5 μm.

In one of the possible or preferred embodiments, a material of the metal surface layer is incorporated into the non-sintered ceramic-based carrier layer.

In one of the possible or preferred embodiments, the material of the metal surface layer is aluminum, an aluminum alloy, copper, a copper alloy, silver, or a silver alloy.

In one of the possible or preferred embodiments, the heat dissipating structure has a heat transfer coefficient from 180 W/mK to 1,000 W/mK.

In one of the possible or preferred embodiments, the heat dissipating structure has a stiffness modulus from 150 GPa to 250 GPa.

In one of the possible or preferred embodiments, the heat dissipating structure has a thermal expansion coefficient from 3 to 20.

In conclusion, in the heat dissipating structure having high thermal conductivity provided by the present disclosure, by virtue of the non-sintered ceramic-based carrier layer incorporated therein having at least one high thermal conductivity material and the metal surface layer coated on an outside of the non-sintered ceramic-based carrier layer, the non-sintered ceramic-based carrier layer and the metal surface layer can be formed into a fully integrated structure that has good thermal conductivity and good stiffness and can be manufactured using a simple process. Therefore, the present disclosure can simplify the manufacturing process of a composite heat dissipating structure, in which a composite system of high thermal conductivity and ceramic materials can be formed without needing to be exposed to high-temperature environments, and can make the heat dissipating structure have a higher heat transfer coefficient.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic view of a ceramic-based carrier layer of a heat dissipating structure having high thermal conductivity that does not undergo an impregnation treatment according to the present disclosure;

FIG. 2 is a schematic enlarged view of an internal structure of the ceramic-based carrier layer as shown in FIG. 1;

FIG. 3 is a schematic view a heat dissipating structure according to a first embodiment of the present disclosure;

FIG. 4 is a schematic enlarged view of an internal structure of a ceramic-based carrier layer of the heat dissipating structure as shown in FIG. 3 that does undergo an impregnation treatment;

FIG. 5 is a schematic view a heat dissipating structure according to a second embodiment of the present disclosure; and

FIG. 6 is a flowchart of a method for manufacturing the heat dissipating structure of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

### First Embodiment

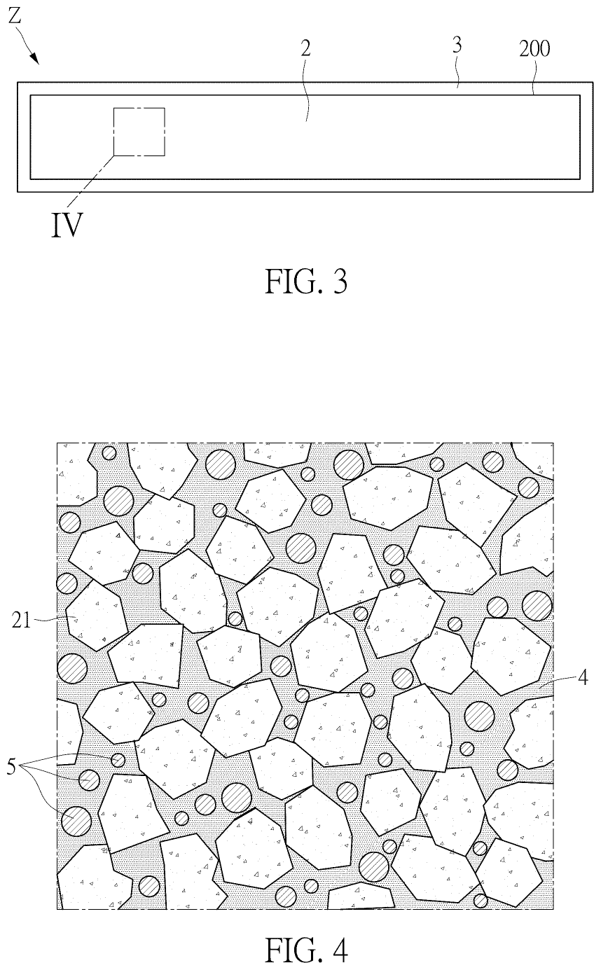

Referring to FIG. 3, a first embodiment of the present disclosure provides a heat dissipating structure Z, which includes a ceramic-based carrier layer 2 and a metal surface layer 3 coated on an outside of the ceramic-based carrier layer 2. In the present embodiment, the metal surface layer 3 completely covers an external surface 200 of the ceramic-based carrier layer 2. A thickness of the ceramic-based carrier layer 2 ranges from 0.1 mm to 6 mm, and a thickness of the metal surface layer 3 ranges from 0.1 mm to 9 mm. However, in addition to the foregoing example, which describes exemplary ranges for thicknesses of each of the ceramic-based carrier layer 2 and the metal surface layer 3, said thicknesses (or thickness ratios) can also be adjusted according to practical requirements.

Referring to FIG. 2, which is to be read in conjunction with FIG. 4, the ceramic-based carrier layer 2 is incorporated therein with at least one high thermal conductivity material 5. The at least one high thermal conductivity material 5 is present in the ceramic-based carrier layer 2 in the form of particles that can have a particle size of less than 5 μm. In the present embodiment, the at least one high thermal conductivity material 5 can be a non-metallic material, and is preferably selected from the group consisting of monocrystalline silicon, diamond, diamond-like carbon, boron nitride, and graphene. In certain embodiments, the at least one high thermal conductivity material 5 can be a metallic material. Furthermore, the at least one high thermal conductivity material 5 can be of the same material as that of a metallic material 4 of the metal surface layer 3, or can be different from the metallic material 4. The metallic material 4 of the metal surface layer 3 can be aluminum, an aluminum alloy, copper, a copper alloy, silver, or a silver alloy.

It should be noted that the ceramic-based carrier layer 2 is formed by molding a ceramic material powder together with a ceramic binder, in which powder particles are joined together by the ceramic binder, rather than performing a sintering treatment during a molding process (such as a cold molding or hot molding process). Since a working temperature used for compression molding is lower than that used for sintering, and the compression molding allows for a shorter processing time, the ceramic-based carrier layer 2 can be obtained in an easier and time-saving manner. Afterwards, a heating treatment can be performed on the ceramic-based carrier layer 2 so as to remove the ceramic binder.

More specifically, the ceramic-based carrier layer 2 has pore structures 20 therein that are formed after removing the ceramic binder, and the at least one high thermal conductivity material 5 is filled into the pore structures 20. In the present embodiment, the ceramic-based carrier layer 2 has a porosity of less than 65%. Furthermore, ceramic materials suitable for use in the present disclosure include, but are not limited to, silicon carbide, silicon dioxide, aluminum oxide, aluminum nitride, gallium nitride, and cubic boron nitride.

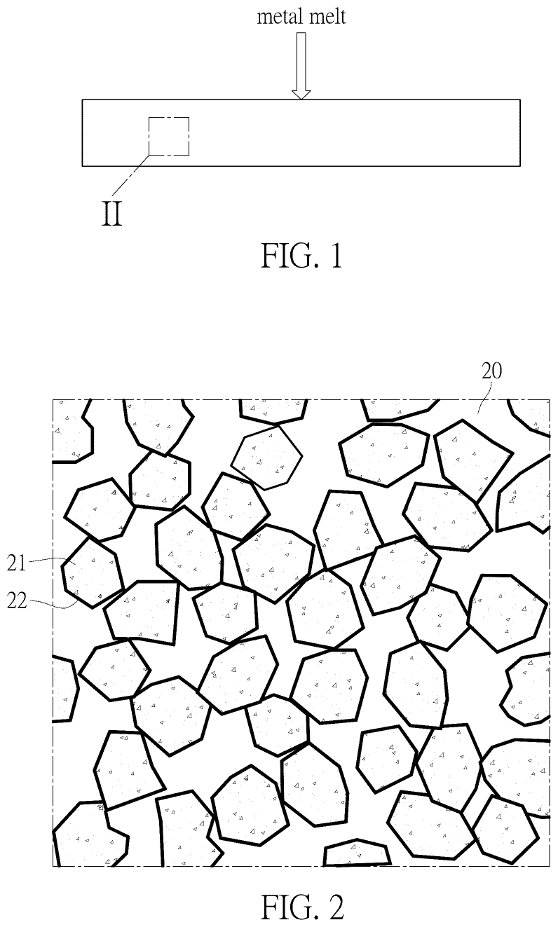

Reference is made to FIG. 1, which is to be read in conjunction with FIG. 3 and FIG. 4. In practice, the metal surface layer 3 can be formed by an impregnation treatment with a metal melt, in which a metallic material 4 contained in the metal melt can penetrate into the pore structures 20 of the ceramic-based carrier layer 2. Therefore, in addition to the at least one high thermal conductivity material 5, the pore structures 20 are also filled with the metallic material 4 of the metal surface layer 3.

In practice, the at least one high thermal conductivity material 5 can be contained in the metal melt and penetrates into the pore structures 20 of the ceramic-based carrier layer 2 along with the metallic material 4. As a result, the metal surface layer 3 also has the at least one high thermal conductivity material 5 therein.

The heat dissipating structure Z as described above has a heat transfer coefficient from 180 W/mK to 1,000 W/mK, a stiffness modulus from 150 GPa to 250 GPa, and a thermal expansion coefficient from 3 to 20. Therefore, the heat dissipating structure Z according to the first embodiment of the present disclosure can exhibit rigid and lightweight properties of a ceramic material, as well as highly thermally conductive properties of a high thermal conductivity material, and is easy to be manufactured.

### Second Embodiment

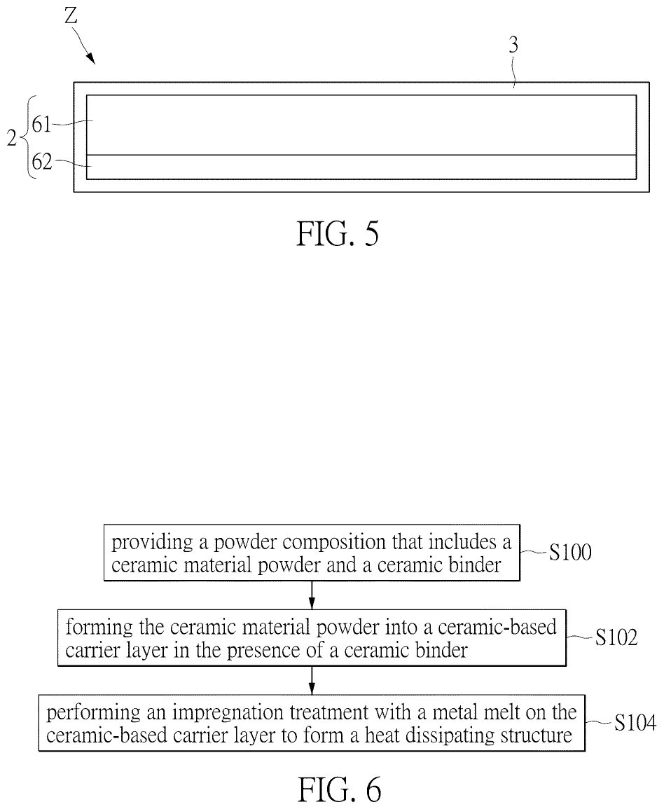

Referring to FIG. 5, a second embodiment of the present disclosure provides a heat dissipating structure Z, which includes a ceramic-based carrier layer 2 and a metal surface layer 3 coated on an outside of the ceramic-based carrier layer 2. The difference between the present embodiment and the first embodiment is as follows: the ceramic-based carrier layer 2 includes a metal-ceramic composite layer 61 and a ceramic layer 62.

Reference is made to FIG. 4. In the present embodiment, the metal-ceramic composite layer 61 is stacked on the ceramic layer 62 and are both covered by the metal surface layer 3. However, such an example of a stack relationship between the metal-ceramic composite layer 61 and the ceramic layer 62 is not meant to limit the scope of the present disclosure. For example, the ceramic-based carrier layer 2 can be provided to have the stack relationship, with the ceramic layer 62 being stacked on the metal-ceramic composite layer 61, or other possible stack relationships. The metal-ceramic composite layer 61 incorporates therein a metallic material 4 and a thermal conductivity material 5. That is, the metal-ceramic composite layer 61 is a composite of a ceramic material, the metallic material 4, and the thermal conductivity material 5. The ceramic layer 62 does not incorporate therein the metallic material 4 and the thermal conductivity material 5. That is, the ceramic layer 62 is composed only of a ceramic material. The thermal conductivity material 5 can be a non-metallic material, and is preferably selected from the group consisting of monocrystalline silicon, diamond, diamond-like carbon, boron nitride, and graphene. In certain embodiments, the high thermal conductivity material 5 can be a metallic material. Furthermore, the high thermal conductivity material 5 can be the same material as the metallic material 4 of the metal surface layer 3, or can be different from the metallic material 4. The metallic material 4 of the metal surface layer 3 can be aluminum, an aluminum alloy, copper, a copper alloy, silver, or a silver alloy.

Similarly, in the second embodiment, the ceramic-based carrier layer 2 does not undergo a sintering treatment, and is formed by molding a ceramic material powder together with a ceramic binder and undergoing a heat treatment to have pore structures 20 therein that are formed after removing the ceramic binder. However, in the present embodiment, when the ceramic-based carrier layer 2 is impregnated with a metal melt, the metallic material 4 of the metal surface layer 3 and the high thermal conductivity material 5 do not completely fill all the pores of the ceramic-based carrier layer 2, and only fill parts of the pores arranged along a thickness of the ceramic-based carrier layer 2. In an example as shown in FIG. 5, only pores in an upper portion of the ceramic-based carrier layer 2 are filled, rather than a lower portion. Accordingly, the ceramic layer 62 not containing the metallic material 4 of the metal surface layer 3 and the high thermal conductivity material 5 and the metal-ceramic composite layer 61 containing the metallic material 4 of the metal surface layer 3 and/or the high thermal conductivity material 5 are alternately stacked to form a multilayered structure.

However, the aforementioned description on the distribution of the metal-ceramic composite layer 61 and the ceramic layer 62 in the ceramic-based carrier layer 2 is merely an example, and other possible distributions should also be within the scope of the present disclosure according to practical requirements.

Compared to the first embodiment, the heat dissipating structure Z of the second embodiment further includes the ceramic layer 62 and can thus exhibit more noticeable properties of ceramic materials, such as higher brittleness.

The relevant technical details mentioned in the first embodiment are still valid in the present embodiment. For the sake of brevity, duplicate descriptions are omitted herefrom. Similarly, the relevant technical details mentioned in the present embodiment can also be applied to the first embodiment.

### Third Embodiment

Referring to FIG. 6, a flowchart of a method for manufacturing the heat dissipating structure Z of the present disclosure is shown. Firstly, step S100 is to provide a powder composition that includes a ceramic material powder and a ceramic binder, and, if necessary, can further include other additives.

Next, step S102 is to form the ceramic material powder into a ceramic-based carrier layer 2 that has a basic shape required for practical applications by a molding process (such as a cold molding or hot molding process) in the presence of a ceramic binder, in which the ceramic material powder is combined with the ceramic binder. As shown in FIG. 2, in a molding process, the ceramic binder 22 can be coated on an external surface of each of powder particles 21, so that the powder particles 21 are joined together by the ceramic binder 22, such as to achieve structural strength that meets the requirements of molding and demolding processes and that is sufficient for maintaining the shape of the ceramic-based carrier layer 2.

In practice, after the molding of the ceramic-based carrier layer 2, a heat treatment can be performed the ceramic-based carrier layer 2 to remove the ceramic binder 22 from the ceramic-based carrier layer 2, as shown in FIG. 4, so as to produce “pseudo-adhesion” between the powder particles 21. Therefore, the ceramic-based carrier layer 2 has pore structures 20 therein that are formed after removing the ceramic binder, and a porosity of the ceramic-based carrier layer 2 can be less than 20%.

Next, step S104 is to perform an impregnation treatment with a metal melt containing a metallic material 4 on the ceramic-based carrier layer 2. As shown in FIG. 1, the metal melt can be provided from a location above the ceramic-based carrier layer 2 and penetrates into the pore structures 20 from a wider surface of the ceramic-based carrier layer 2. Accordingly, the metallic material 4 is filled into the pore structures 20 and coated on an external surface 200 of the ceramic-based carrier layer 2 to form a metal surface layer 3.

In step S104, the metal melt can completely penetrate into all the pores of the ceramic-based carrier layer 2, so as to form the heat dissipating structure as described in the first embodiment. Alternatively, the metal melt does not completely penetrate into all the pores of the ceramic-based carrier layer 2, and only fill parts of the pores arranged along a thickness of the ceramic-based carrier layer 2, so as to form the heat dissipating structure as described in the second embodiment, which includes a metal-ceramic composite layer 61 and a ceramic layer 62.

In the present embodiment, in addition to the metallic material 4, the metal melt can further include a high thermal conductivity material 5, so that in the impregnation treatment, the pore structures 20 of the ceramic-based carrier layer 2 are also filled with the high thermal conductivity material 5. The high thermal conductivity material 5 can be a high thermal conductivity non-metallic material or metallic material. As mentioned above, the high thermal conductivity material 5 can be selected from the group consisting of monocrystalline silicon, diamond, diamond-like carbon, boron nitride, and graphene. The high thermal conductivity material 5 can be the same material as a metallic material 4, or can be different from the metallic material 4. The metallic material 4 of the metal surface layer 3 can be aluminum, an aluminum alloy, copper, a copper alloy, silver, or a silver alloy.

If necessary, between step S102 and step S104, the method can further include an additional step of performing mechanical processing on the ceramic-based carrier layer 2 (not shown in FIG. 6), so as to have the ceramic-based carrier layer 2 with a desired shape or structure. Specifically, the mechanical processing suitable for use in the present disclosure can include cutting, grinding, drilling, or grooving the ceramic-based carrier layer 2, so that the ceramic-based carrier layer 2 has a shape or structure that meets the requirements of subsequent applications such as circuit substrates. It should be understood that if the ceramic-based carrier layer 2 is already formed with a shape or structure, the step of mechanical processing can be omitted.

### Beneficial Effects of the Embodiments

heat dissipating structure having high thermal conductivity provided by the present disclosure, by virtue of the non-sintered ceramic-based carrier layer incorporated therein having at least one high thermal conductivity material and the metal surface layer coated on an outside of the non-sintered ceramic-based carrier layer, can be manufactured by a simplified process at a reduced time cost, and can have properties that meet the requirements of practical applications, such as thermal stability, dielectric properties, and mechanical strength.

Compared to the conventional heat dissipating structure made of a composite material, the ceramic-based carrier layer of the present disclosure can be manufactured in a simple manner under process conditions that are easier to achieve, and the heat dissipating structure of the present disclosure can have good thermally conductive properties of a metallic material and a high thermal conductivity material, and excellent mechanical properties of a ceramic material. Therefore, the production threshold of heat dissipation structures can be lowered, production cost and time can be saved, and a heat dissipation structure suitable for practical applications can be obtained.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A heat dissipating structure having high thermal conductivity, comprising:
a non-sintered ceramic-based carrier layer incorporated therein with at least one high thermal conductivity material; and
a metal surface layer coated on an outside of the non-sintered ceramic-based carrier layer.

2. The heat dissipating structure according to claim 1, wherein the non-sintered ceramic-based carrier layer includes a ceramic layer and a metal-ceramic composite layer stacked on the ceramic layer, and the at least one high thermal conductivity material is incorporated into the metal-ceramic composite layer.

3. The heat dissipating structure according to claim 1, wherein the non-sintered ceramic-based carrier layer has a porosity of less than 65%.

4. The heat dissipating structure according to claim 1, wherein a thickness of the non-sintered ceramic-based carrier layer ranges from 0.1 mm to 6 mm, and a thickness of the metal surface layer ranges from 0.1 mm to 9 mm.

5. The heat dissipating structure according to claim 1, wherein the at least one high thermal conductivity material is selected from the group consisting of monocrystalline silicon, diamond, diamond-like carbon, boron nitride, and graphene.

6. The heat dissipating structure according to claim 1, wherein the at least one high thermal conductivity material is present in the form of particles having a particle size of less than 5 μm.

7. The heat dissipating structure according to claim 1, wherein a material of the metal surface layer is incorporated into the non-sintered ceramic-based carrier layer.

8. The heat dissipating structure according to claim 7, wherein the material of the metal surface layer is aluminum, an aluminum alloy, copper, a copper alloy, silver, or a silver alloy.

9. The heat dissipating structure according to claim 1, wherein the heat dissipating structure has a heat transfer coefficient from 180 W/mK to 1,000 W/mK.

10. The heat dissipating structure according to claim 1, wherein the heat dissipating structure has a stiffness modulus from 150 GPa to 250 GPa.

11. The heat dissipating structure according to claim 1, wherein the heat dissipating structure has a thermal expansion coefficient from 3 to 20.
